(19) United States
(12) Patent Application Publication
(10) Pub. No.: US 2006/0175082 A1
(43) Pub. Date: Aug. 10, 2006

(54) Flexible printed circuit board and connecting method of the same

(75) Inventor: Eiji Tanaka, Higashihiroshima-shi (JP)

Correspondence Address: MORRISON & FOERSTER LLP, 755 PAGE MILL RD, PALO ALTO, CA, 94304-1018, US

(73) Assignee: SHARP KABUSHIKI KAISHA, Osaka-shi (JP)

(21) Appl. No.: 11/350,438

(22) Filed: Feb. 8, 2006

(30) Foreign Application Priority Data
Feb. 8, 2005 (JP) JP2005-032162

(51) Int. Cl. H05K 1/11; H05K 3/36

(52) U.S. Cl. 174/254; 174/261; 29/846

(57) ABSTRACT

A flexible printed circuit board is provided which can make heights of components protruding from the plane of the FPC as low as possible and prevent the bending property of the FPC from being impaired. A foldable fold-back portion is provided at a part of the EPC, and at the time of internal connection of the FPC, a land formed on the flexible printed circuit board main body and a connecting land portion are bonded to each other in a state where the fold-back portion is folded back relative to the flexible printed circuit board main body so that the connecting land portion is laid on the land. Consequently, it is possible to make the heights of the components protruding from the plane of the FPC as low as possible, and prevent the bending property of the FPC from being impaired.

### BACKGROUND OF THE INVENTION

1. Field of the Invention

The present invention relates to a flexible printed circuit board and a connecting method of the same, for example, a technique applied to audiovisual equipment and the like.

In the invention, “a pattern” is synonymous with a conductive pattern and a nonconductive pattern that are formed on a flexible printed circuit board. “Cream solder” is synonymous with a mixture of solder powder and flux in paste form. The cream solder is also referred to as solder paste.

2. Description of the Related Art

FIG. 5 is a perspective view schematically showing the essential part of a flexible printed circuit board of a related art. So far, there has been practically used a technique for internal connection by using, for example, a 0 Ω chip resistor, a jumper wire 1 (a lead wire) and the like on a flexible printed circuit board (abbreviated to FPC) or by using a multilayer FPC {refer to Japanese Unexamined Patent Publication JP-A 58-37987 (1983), for example}.

In most cases, at a part to which the FPC is applied, and there is a need to make a volume of equipment small and make heights of components protruding from the plane of the FPC as low as possible. However, as to the conventional FPC, the height of the 0 Ω chip resistor, the jumper wire 1 and the like must be secured on the FPC to mount these components harder than the FPC itself having flexibility so that the internal connection is achieved. Thus, it is impossible to make the heights of the components protruding from the plane of the FPC as low as possible, and the bending property of the FPC is impaired.

### SUMMARY OF THE INVENTION

An object of the invention is to provide a flexible printed circuit board and a connecting method of the same, which can make heights of components protruding from the plane of the FPC as low as possible and prevent the bending property of the FPC from being impaired.

The invention provides a flexible printed circuit board comprising:

a flexible printed circuit board main body having a land; and

a fold-back portion formed integrally with the flexible printed circuit board main body so as to be foldable, the fold-back portion having a connecting land portion provided so that a land formed on the flexible printed circuit board main body and the connecting land portion are laid on each other when the fold-back portion is folded back,

wherein internal electrical connection can be achieved by bonding the land and the connecting land portion in a state where the fold-back portion is folded back relative to the flexible printed circuit board main body so that the connecting land portion is laid on the land formed on the flexible printed circuit board main body.

According to the invention, the flexible printed circuit board (may be referred to as FPC) is formed so as to be capable of internal electrical connection. The flexible printed circuit board comprises a flexible printed circuit board main body having a land; and a fold-back portion formed integrally with the flexible printed circuit board main body so as to be foldable, the fold-back portion having a connecting land portion provided so as to be laid on a land formed on the flexible printed circuit board main body when the fold-back portion is folded back. In the other words, at a part of the FPC, the foldable fold-back portion is provided. At the time of internal connection of the FPC, in a state of having the fold-back portion folded back relative to the flexible printed circuit board main body so that the connecting land portion is laid on the land formed on the flexible printed circuit board main body, the land and the connecting land portion are bonded to each other. In this state, it becomes possible to achieve the internal electrical connection of the flexible printed circuit board. Since the internal electrical connection is made achievable by folding back a part of the FPC as described above, it is possible to make heights of components protruding from the plane of the FPC as low as possible. Without using components for internal connection that are harder than an FPC as in a related art, it is possible to internally connect an FPC. Thus, it is possible to prevent the bending property of an FPC having flexibility from being impaired. Therefore, it becomes possible to increase the versatility and durability of an FPC. As compared with a case of using a multilayer board as in the related art, it is possible to reduce the cost because it is possible to realize internal electrical connection by using a one-layer board.

Further, in the invention, it is preferable that the connecting land portion is formed at a peripheral end portion of the flexible printed circuit board.

According to the invention, the connecting land portion is formed at the peripheral end portion of the FPC, so that it is possible to visually check a connection state between the land and the connecting land portion after the fold-back portion having the connecting land portion is folded back and internal connection is completed. Therefore, it becomes possible to increase the reliability of a flexible printed circuit board in which the internal connection is achieved.

Further, in the invention, it is preferable that location holes are formed on the flexible printed circuit board main body and the fold-back portion, respectively, so that the location holes coincide with each other when the fold-back portion is folded back so that the land formed on the flexible printed circuit board main body and the connecting land portion corresponding thereto are laid on each other.

According to the invention, the location holes are formed on the flexible printed circuit board main body and the fold-back portion, respectively, so that the location holes coincide with each other when the fold-back portion is folded back so that the land formed on the flexible printed circuit board main body and the connecting land portion corresponding thereto are laid on each other. Consequently, by making these location holes coincide with each other when the fold-back portion is fold back, the land formed on the flexible printed circuit board main body and the connecting land portion corresponding thereto can be easily laid on each other.

Furthermore, the invention provides a connecting method for connecting a flexible printed circuit board comprising a flexible printed circuit board main body having a land; and a fold-back portion formed integrally with the flexible printed circuit board main body so as to be foldable, the fold-back portion having a connecting land portion which is provided so as to correspond to a land formed on the flexible printed circuit board main body, the connecting method comprising the steps of:

applying cream solder to the land formed on the flexible printed circuit board main body to be connected;

laying the land formed on the flexible printed circuit board main body and the connecting land portion corresponding thereto on each other by folding back the fold-back portion relative to the flexible printed circuit board main body; and

making solder connection between the land formed on the flexible printed circuit board main body and the connecting land portion corresponding thereto by reflow.

According to the invention, internal electrical connection is completed by folding back a part of an FPC, so that it is possible to make the heights of the components protruding from the plane of an FPC as low as possible, and moreover, it is possible to prevent the bending property of an FPC having flexibility from being impaired. In particular, since the step of making the solder connection by use of reflow is comprised, it is possible to shorten a working time required for solder connection.

### BRIEF DESCRIPTION OF THE DRAWINGS

Other and further objects, features, and advantages of the invention will be more explicit from the following detailed description taken with reference to the drawings wherein:

FIG. 1 is a view showing coverlay openings and its outline to which a flexible printed circuit board according to an embodiment of the invention is applied;

FIG. 2 is a view showing a relation between a connecting land portion of a fold-back portion and a land of a flexible printed circuit main body;

FIG. 3 is a view schematically showing the flexible printed circuit board in which internal electrical connection is completed;

FIG. 4 is a flowchart describing in stages the connecting method of the flexible printed circuit board relating to the embodiment of the invention; and

FIG. 5 is a perspective view schematically showing an essential part of a flexible printed circuit board of a related art.

### DETAILED DESCRIPTION OF THE PREFERRED EMBODIMENTS

Now referring to the drawings, a preferred embodiment of the invention is described below.

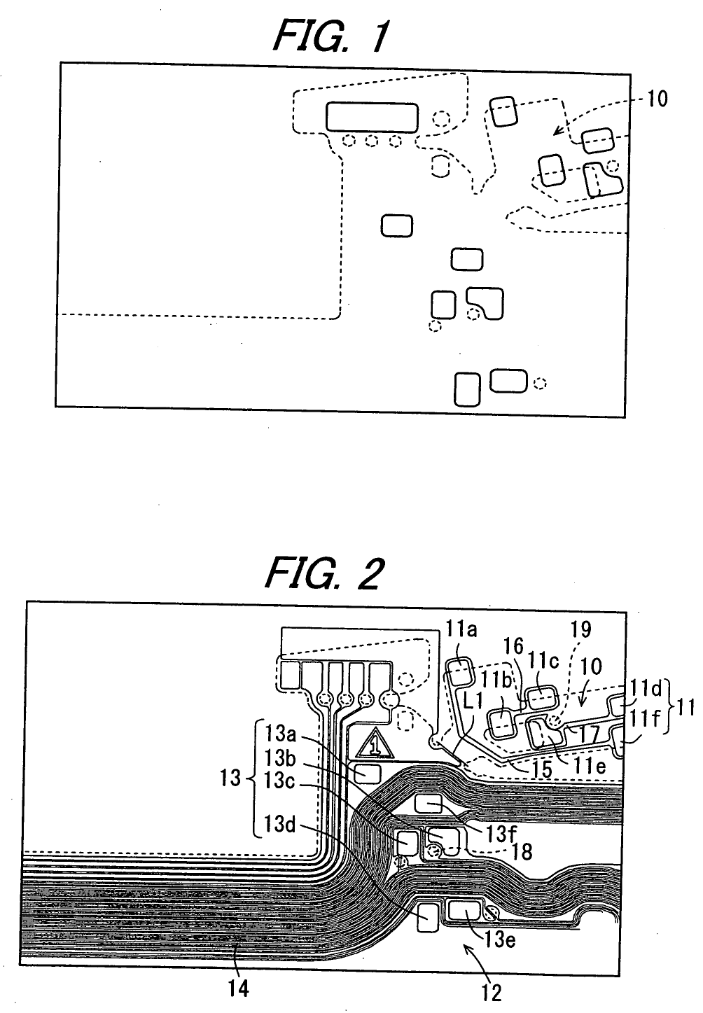

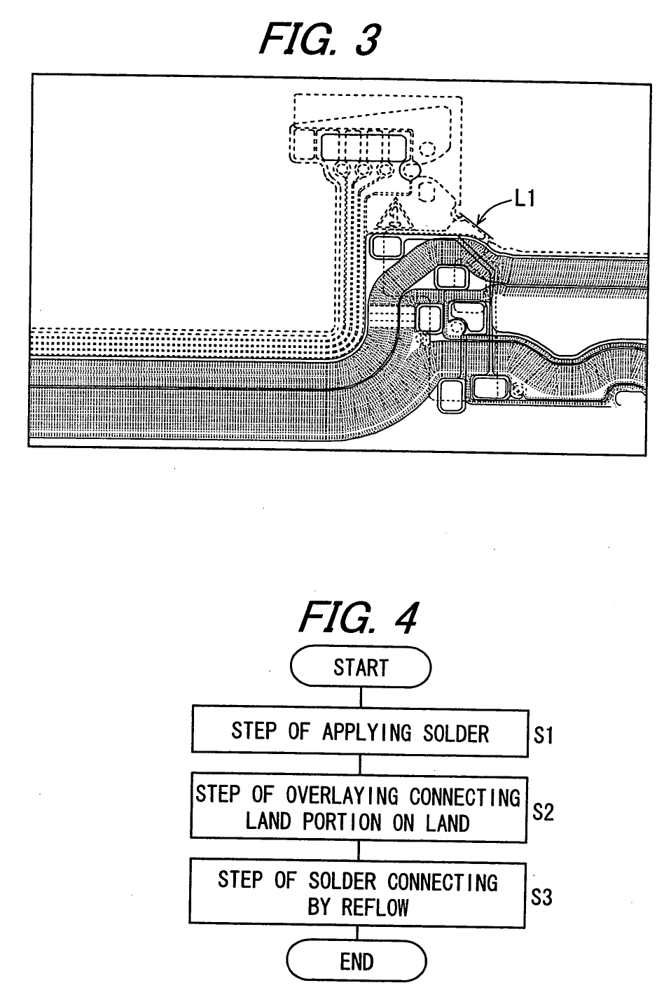

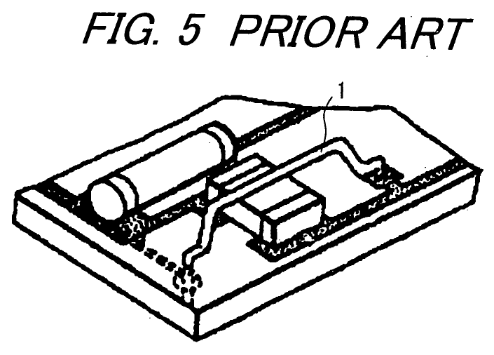

An embodiment of the invention will be described below with reference to the drawings. A flexible printed circuit board relating to the present embodiment is applied to, for example, audiovisual equipment and the like. However, it is not limited to use for audiovisual equipment. The following description contains the description of a connecting method of a flexible printed circuit board as well. FIG. 1 is a view showing coverlay openings and its outline to which the flexible printed circuit board according to the embodiment of the invention is applied. FIG. 2 is a view showing the relation between a connecting land portion 11 of a fold-back portion 10 and a land 13 of a flexible printed circuit main body 12. FIG. 3 is a view schematically showing the flexible printed circuit board in which internal electrical connection is completed.

A flexible printed circuit board (abbreviated to FPC) is composed of, for example, a pattern 14 and a coverlay film coated thereon, which pattern 14 is formed by etching a sheet-shaped copper foil made by bonding the copper foil acting as a conductor to a flexible thin polyimide film. At a part of the FPC, the foldable fold-back portion 10 is provided. The fold-back portion 10 is folded back so as to correspond to the land 13 of the flexible printed circuit board main body 12 with respect to a prescribed fold-back line L1. In other words, a part protruding toward the periphery from the fold-back line L1 of the entire FPC is equivalent to the fold-back portion 10. In more detail, the flexible printed circuit board comprises the flexible printed circuit board main body 12 having the land 13; and the fold-back portion 10 formed integrally with the flexible printed circuit board main body 12 so as to be foldable.

The fold-back portion 10 is provided with the connecting land portion 11. In the other words, the fold-back portion 10 has the connecting land portion 11 provided so as to be laid over the land 13 formed on the flexible printed circuit board main body 12 when the fold-back portion 10 is folded back. The fold-back portion 10 can be folded back relative to the flexible printed circuit board main body 12 so that the connecting land portion 11 is laid on the land 13 formed on the flexible printed circuit board main body. The connecting land portion 11 is bonded to the land 13 formed on the flexible printed circuit board main body in a state where the fold-back portion 10 is folded back relative to the flexible printed circuit board main body 12. In this state, the internal electrical connection of the flexible printed circuit board is achieved. The connecting land portion 11 is formed at the peripheral end portion of the FPC. However, the connecting land portion 11 may be formed at a part other than the peripheral end portion of the FPC. The connecting land portion 11 includes a first copper foil land 11a, a second copper foil land 11b, a third copper foil land 11c, a fourth copper foil land 11d, a fifth copper foil land 11e, and a sixth copper foil land 11f. In these copper foil lands 11a to 11f, the first copper foil land 11a and the sixth copper foil land 11f are connected by a copper foil 15, the second copper foil land 11b and the third copper foil land 11c are connected by a copper foil 16, and the fourth copper foil land 11d and the fifth copper foil land 11e are connected by a copper foil 17.

On the flexible printed circuit board main body 12 of the FPC, the land 13 is formed. The land 13 includes a seventh copper foil land 13a, an eighth copper foil land 13b, a ninth copper foil land 13c, a tenth copper foil land 13d, an eleventh copper foil land 13e, and a twelfth copper foil land 13f. The respective copper foil lands are independently provided across the pattern 14. As shown in FIG. 2, the seventh to twelfth copper foil lands 13a, 13b, 13c, 13d, 13e and 13f are positioned so as to be axisymmetric to the first to sixth copper foil lands 11a, 11b, 11c, 11d, 11e and 11f with respect to the fold-back line L1. That is to say, the seventh and first copper foil lands 13a and 11a are placed so as to be axisymmetric, and the eighth and fifth copper foil lands 13b and 11e are placed so as to be axisymmetric. The ninth and third copper foil lands 13c and 11c are placed so as to be axisymmetric, and the tenth and fourth copper foil lands 13d and 11d are placed so as to be axisymmetric. The eleventh and sixth copper foil lands 13e and 11f are placed so as to be axisymmetric, and the twelfth and second copper foil lands 13f and 11b are placed so as to be axisymmetric. Moreover, the flexible printed circuit board main body 12 and the fold-back portion 10 are provided with location holes 18 and 19, respectively. The location holes 18 and 19 are also positioned so as to be axisymmetric with respect to the fold-back line L1. That is to say, these location holes 18 and 19 are formed on the flexible printed circuit board main body 12 and the fold-back portion 10, respectively, so that the location holes 18 and 19 coincide with each other when the fold-back portion 10 is folded back so that the land 13 formed on the flexible printed circuit board main body and the connecting land portion 11 are laid on each other. By making these location holes 18 and 19 coincide with each other when the fold-back portion 10 is fold back, the land 13 and the connecting land portion 11 can be easily laid on each other.

FIG. 4 is a flowchart describing in stages the connecting method of the flexible printed circuit board relating to the embodiment of the invention. The description will be made with reference to FIGS. 1 to 3 as well. In a pre-folded state of the FPC shown in FIG. 2, for electrically connecting by internal connection the seventh copper foil land 13a and the eleventh copper foil land 13e, the twelfth copper foil land 13f and the ninth copper foil land 13c, and the tenth copper foil land 13d and the eighth copper foil land 13b, respectively, in the seventh to twelfth copper foil lands 13a, 13b, 13c, 13d, 13e and 13f, the following steps will be executed. That is to say, at the time of mounting of components not shown in the drawings on the FPC, in a component mounting process, cream solder is applied to the coverlay opening portions by the use of a metal mask, components are then mounted on the other parts, and thereafter, the FPC is put into a reflow furnace to melt the solder on each portion so that the components are mounted on the FPC.

In the present embodiment, cream solder is applied by the use of a metal mask to the coverlay opening portions shown in FIG. 1 in the component mounting process (step S1), and the fold-back portion 10 is folded back relative to the flexible printed circuit board main body 12 with respect to the fold-back line L1. In this case, the location holes 18 and 19 are made to coincide with each other, and the fold-back portion is folded on the fold-back line L1 and temporarily fixed by, for example, a tape and the like (step S2). In this state, the cream solders on the seventh copper foil land 13a and the first copper foil land 11a come in contact, the cream solders on the eighth copper foil land 13b and the fifth copper foil land 11e come in contact, the cream solders on the ninth copper foil land 13c and the third copper foil land 11c come in contact, the cream solders on the tenth copper foil land 13d and the fourth copper foil land 11d come in contact, the cream solders on the eleventh copper foil land 13e and the sixth copper foil land 11f come in contact, and the cream solders on the twelfth copper foil land 13f and the second copper foil land 11b come in contact. On the other hand, on the fold-back portion 10, the first copper foil land 11a and the sixth copper foil land 11f are connected by the copper foil 15, the second copper foil land 11b and the third copper foil land 11c are connected by the copper foil 16, and the fourth copper foil land 11d and the fifth copper foil land 11e are connected by the copper foil 17, and in this folded back state, the FPC is put into a component mounting machine in the component mounting process to mount the components not shown in the drawings.

After the components are mounted, the FPC is put into a reflow furnace. Here, the respective components are soldered, and the cream solders, which are applied to the respective copper foil lands of the folded-back connecting land portion 11 so as to come in contact therewith, are melted, whereby soldering for FPC internal connection is completed (step S3). That is to say, as to internal wiring of the FPC, the first and sixth copper foil lands 11a and 11f, the second and third copper foil lands 11b and 11c, and the fourth and fifth copper foil lands 11d and 11e of the fold-back portion are soldered so as to correspond to the seventh and eleventh copper foil lands 13a and 13e, the twelfth and ninth copper foil lands 13f and 13c, and the tenth and eighth copper foil lands 13d and 13b, respectively, whereby the aimed connections of the seventh and eleventh copper foil lands 13a and 13e, the twelfth and ninth copper foil lands 13f and 13c, and the tenth and eighth copper foil lands 13d and 13b are completed.

According to the flexible printed circuit board and the connecting method of the same described above, a part of the FPC is provided with the foldable fold-back portion 10. At the time of internal connection of the FPC, the connecting land portion 11 is folded back and bonded so as to correspond to the land 13 of the flexible printed circuit board main body 12. Internal electrical connection is completed in this state. Since internal electrical connection is completed by folding a part of the FPC as described above, it is possible to make heights of components protruding from the plane of the FPC as low as possible. Therefore, equipment provided with the FPC can be made slim. Without using components for internal connection that are harder than an FPC as in the related art, it is possible to achieve internal connection in an FPC. Thus, it is possible to prevent the bending property of an FPC having flexibility from being impaired. Therefore, it becomes possible to increase the versatility and durability of an FPC. As compared with a case of using a multilayer board as in the related art, it is possible to reduce the manufacture cost because it is possible to realize internal electrical connection by using a one-layer board.

Further, since the connecting land portion 11 is formed at the peripheral end portion of the FPC, it is possible to visually check a connection state after the connecting land portion 11 is folded back and internal connection is completed. Therefore, it becomes possible to increase the reliability of the FPC that is internally connected. Moreover, since the step of making the solder connection by use of reflow is comprised, it is possible to shorten a working time required for solder connection. Thus, it becomes possible to decrease the working man-hours, and further reduce the manufacture cost.

As to the FPC relating to the present embodiment, the FPC having the fold-back portion not yet folded may be distributed (refer to FIG. 2), or the FPC having the fold-back portion temporarily fixed by the tape and the like may be distributed. Besides, it is also possible to embody the invention in forms with various changes added without departing from the scope of the invention.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and the range of equivalency of the claims are therefore intended to be embraced therein.

What is claimed is:

1. A flexible printed circuit board comprising:
a flexible printed circuit board main body having a land; and
a fold-back portion formed integrally with the flexible printed circuit board main body so as to be foldable, the fold-back portion having a connecting land portion provided so that a land formed on the flexible printed circuit board main body and the connecting land portion are laid on each other when the fold-back portion is folded back,
wherein internal electrical connection can be achieved by bonding the land and the connecting land portion in a state where the fold-back portion is folded back relative to the flexible printed circuit board main body so that the connecting land portion is laid on the land formed on the flexible printed circuit board main body.

2. The flexible printed circuit board of claim 1, wherein the connecting land portion is formed at a peripheral end portion of the flexible printed circuit board.

3. The flexible printed circuit board of claim 1, wherein location holes are formed on the flexible printed circuit board main body and the fold-back portion, respectively, so that the location holes coincide with each other when the fold-back portion is folded back so that the land formed on the flexible printed circuit board main body and the connecting land portion corresponding thereto are laid on each other.

4. A connecting method for connecting a flexible printed circuit board comprising a flexible printed circuit board main body having a land; and a fold-back portion formed integrally with the flexible printed circuit board main body so as to be foldable, the fold-back portion having a connecting land portion which is provided so as to correspond to a land formed on the flexible printed circuit board main body, the connecting method comprising the steps of:
applying cream solder to the land formed on the flexible printed circuit board main body to be connected;
laying the land formed on the flexible printed circuit board main body and the connecting land portion corresponding thereto on each other by folding back the fold-back portion relative to the flexible printed circuit board main body; and
making solder connection between the land formed on the flexible printed circuit board main body and the connecting land portion corresponding thereto by reflow.
